(19) United States
(12) Patent Application Publication
(10) Pub. No.: US 2019/0206483 A1
(43) Pub. Date: Jul. 4, 2019

(54) SRAM STRUCTURE SUPPORTING TRANSPOSED READING

(71) Applicant: UX FACTORY CO., LTD., Daejeon (KR)

(72) Inventor: Kyeong Ryeol BONG, Seoul (KR)

(73) Assignee: UX FACTORY CO., LTD., Daejeon (KR)

(21) Appl. No.: 15/882,983

(22) Filed: Jan. 29, 2018

(30) Foreign Application Priority Data
Dec. 29, 2017 (KR) 10-2017-0184725

(51) Int. Cl. G11C 11/419; G11C 11/418

(52) U.S. Cl. CPC G11C 11/419; G11C 11/418

(57) ABSTRACT

An SRAM cell is constructed by 7 transistors supporting transposed reading in addition to normal reading and writing, thereby retrieving a plurality of data through one-time reading even during column-wise parallel processing as well as row-wise parallel processing. Therefore, delay caused by multiple-time reading and increase in power consumption, occurring in a conventional SRAM, can be solved.

### BACKGROUND OF THE INVENTION

### Field of the Invention

The present invention relates to a static random access memory (SRAM) structure supporting transposed reading and, more particularly, to an SRAM structure supporting transposed reading through 7 transistors supporting transposed reading in addition to normal reading and writing.

### Description of the Related Art

Recent artificial intelligence (AI) technology is implemented by deep neural network algorithms for learning patterns from a massive amount of data.

In a conventional central processing unit (CPU), it is difficult to rapidly process a huge amount of calculations required for a deep neural network and, therefore, hardware technology needs to be supported.

To rapidly process an algorithm requiring a large amount of matrix calculations as in the deep neural network, parallel processing hardware capable of simultaneously processing a plurality of data is indispensable.

An SRAM semiconductor may be used to maximize the effect of parallel processing by maintaining an operating state of such hardware.

As opposed to a dynamic random access memory (DRAM) which is mainly manufactured in the form of an additional chip through a DRAM process, an SRAM is mainly manufactured through a logic process and is integrated into one chip together with an operator. Therefore, if parallel processing hardware simultaneously processes a plurality of data, it is necessary to smoothly supply required data without delay by constructing the hardware to have wide bit width.

The SRAM includes an array of cells for storing bits, in which each row is connected to one wordline shared by cells in the same row and each column is connected to two bit lines BL and BLB shared by cells in the same column.

While reading data, two bit lines are charged to a power voltage VDD. If a wordline corresponding to an address to be read is activated, a voltage charged in any one of the bit lines BL and BLB is discharged and the other bit line maintains a charged state, according to data (0 or 1) stored in selected cells.

A sense amplifier is connected to each of the bit lines BL and BLB and determines whether a value stored in a cell is 0 or 1 by comparing the magnitudes of the bit lines BL and BLB.

When a plurality of data is simultaneously read using an SRAM having a wide bit width, only a data group stored in the same row of the SRAM can be restrictively accessed at the same time.

This shows limitations caused by the structure of the SRAM. Basically, the SRAM activates one wordline corresponding to an address which is input during reading or writing and cells of the SRAM of one row connected to the corresponding wordline are selected for reading or writing.

However, in matrix calculation, column-wise data parallel processing is indispensable in many cases in addition to row-wise data parallel processing.

If a plurality of column-wise data is read using a conventional SRAM, a process of collecting data through reading many times is inevitable unlike row-wise parallel processing capable of retrieving a plurality of data through reading one time.

Therefore, during column-wise parallel processing, entire calculation speed is reduced due to delay consumed to perform reading many times and power consumption increases due to increase in the number of operations of the SRAM.

### SUMMARY OF THE INVENTION

Therefore, the present invention has been made in view of the above problems, and it is an object of the present invention to provide an SRAM structure supporting transposed reading, for solving delay caused by reading many times and increase in power consumption by constructing an SRAM cell including 7 transistors supporting transposed reading in addition to normal reading and writing and retrieving a plurality of data through reading one time even during column-wise parallel processing as well as row-wise parallel processing.

In accordance with the present invention, the above and other objects can be accomplished by the provision of a static random access memory (SRAM) structure supporting transposed reading, including a T-SRAM configured to add one read transistor to a normal SRAM cell including four transistors constituting two storage nodes in the form of an inverter latch and two access transistors connected between the storage nodes and bit lines of the cell under control of a wordline signal, wherein, during row-wise processing and column-wise processing through the read transistor, a plurality of data is read by a one-time reading operation.

A gate terminal of the read transistor may be connected to one of the two storage nodes and the other two terminals of the read transistor may be respectively connected to a metal line shared by cells in the same row and a metal line shared by cells in the same column.

During row-wise reading through the read transistor, a horizontal metal line may be used as a wordline and a vertical metal line may be used as a bit line and, during column-wise transposed reading through the read transistor, the vertical metal line may be used as the wordline and the horizontal metal line may be used as the bit line.

The T-SRAM cell may store data including a plurality of bits by allocating one bank to each bit so that data allocated to the same position may be read during reading and transposed reading.

A wordline and two bit lines of the normal SRAM cell may be used for writing.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a diagram illustrating a parallel processing process of row-wise data using a conventional SRAM;

FIG. 2 is a diagram illustrating a parallel processing process of column-wise data using a conventional SRAM;

FIG. 3 is a diagram illustrating a parallel processing process of column-wise data using an SRAM supporting transposed reading according to an embodiment of the present invention;

FIG. 4 is a diagram illustrating an SRAM structure supporting transposed reading according to an embodiment of the present invention; and

FIGS. 5 and 6 are diagrams illustrating a process of storing data in a bank using an SRAM supporting transposed reading according to an embodiment of the present invention.

### DETAILED DESCRIPTION OF THE INVENTION

Hereinafter, embodiments of the present invention will be described in detail with reference to the accompanying drawings so that the above and other aspects of the present invention will be easily understood and realized by those skilled in the art.

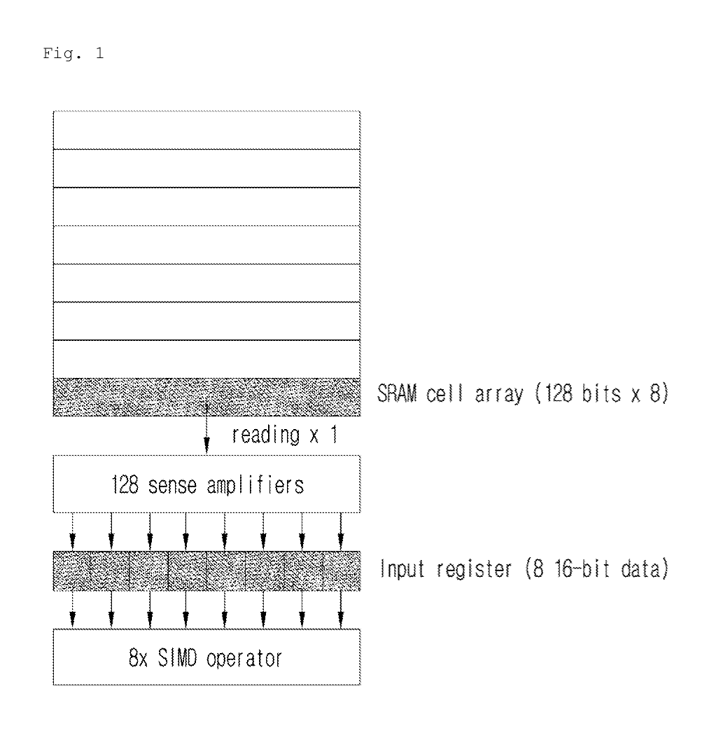

An example of parallel processing of row-wise data using a conventional SRAM with respect to 8 16-bit data is illustrated in FIG. 1. When a single instruction multiple data (SIMD) operator for performing the same operation with respect to the 8 16-bit data and an SRAM of a 128-bit width are used, data in the same row can be retrieved by one-time reading through 128 sense amplifiers.

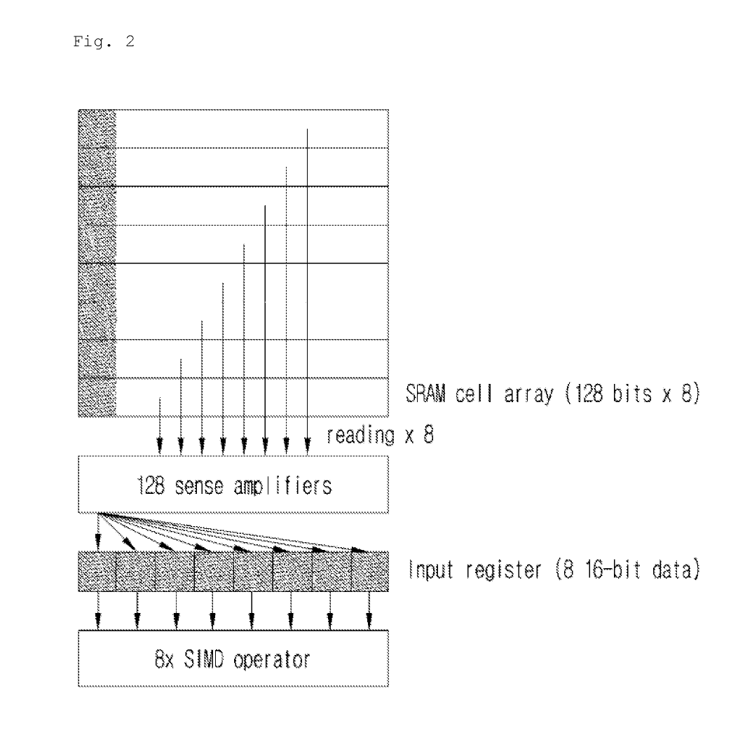

An example of parallel processing of column-wise data using a conventional SRAM with respect to 8 16-bit data is illustrated in FIG. 2. When an SIMD operator and the conventional SRAM are used, since the 8 16-bit data in the same column are stored in 8 different rows, all data is retrieved by performing row-wise SRAM reading 8 times and then parallel processing of column-wise data is performed by performing an SIMD operation.

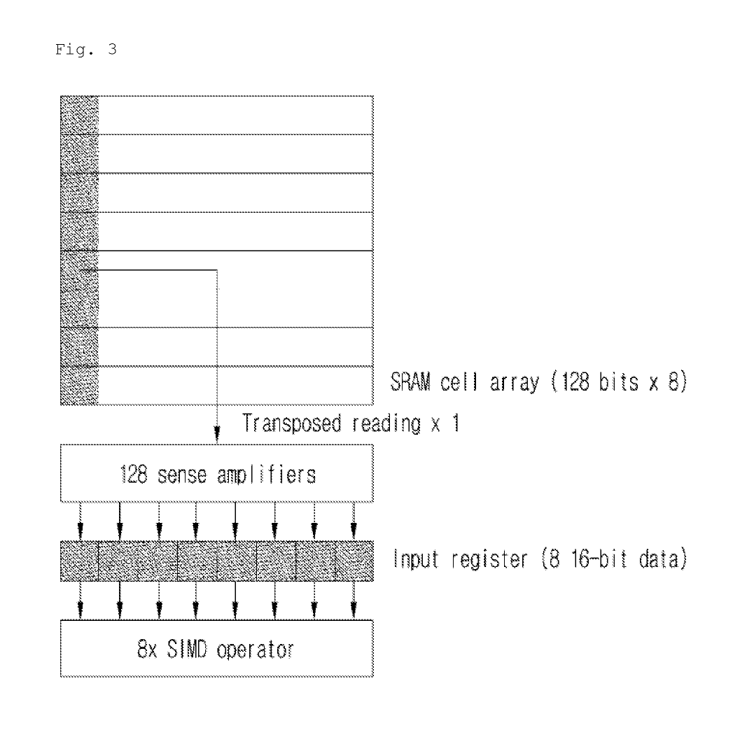

As illustrated in FIG. 3, an SRAM (T-SRAM) supporting transposed reading according to an embodiment of the present invention is constructed to perform transposed reading in addition to reading and writing of a conventional SRAM, using an SRAM cell including 7 transistors.

FIG. 3 illustrates parallel processing of 8 16-bit data. When an SRAM supporting transposed reading and an SIMD operator are used, the 8 16-bit data in the same column are retrieved only through transposed reading of one time to perform an SIMD operation.

That is, during transposed reading, one column is selected and reading from cells included in the selected column is possible.

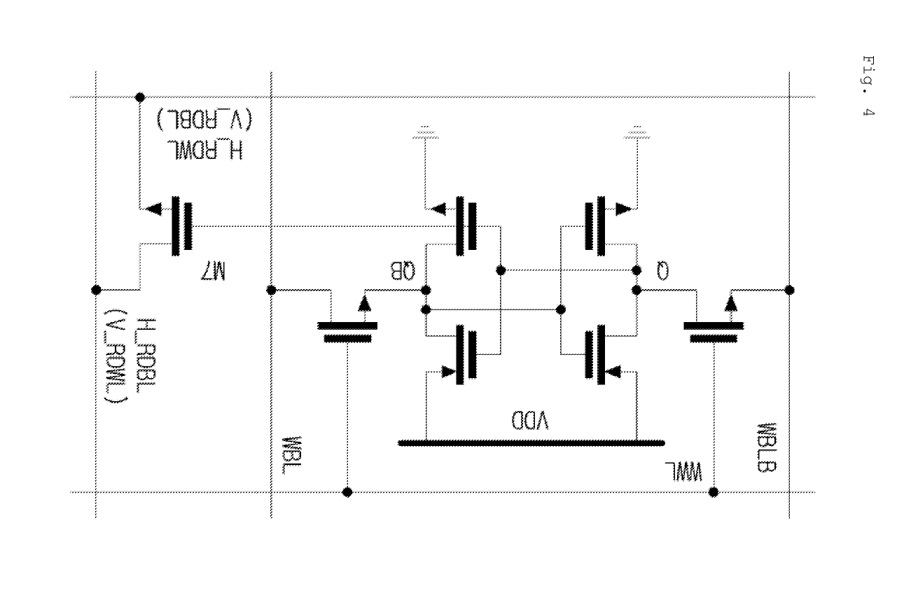

As illustrated in FIG. 4, an SRAM cell supporting transposed reading according to the present invention is configured to add a read transistor M7 for performing one reading operation and transposed reading to a 6-transistor SRAM including four transistors constituting two storage nodes Q and QB in the form of an inverter latch and two access transistors connected between the storage nodes Q and QB of the cell and bit lines WBL and WBLB under control of a wordline WWL signal.

The gate terminal of the read transistor M7 is connected to one of the two storage nodes Q and QB and the other two terminals of the read transistor M7 are respectively connected to a horizontal metal line H_RDWL shared by cells in the same row and a vertical metal line H_RDBL shared by cells in the same column.

In the SRAM supporting transposed reading, a wordline WWL corresponding to a wordline of a conventional SRAM cell and two bit lines WBL and WBLB corresponding to bit lines of the conventional SRAM cell are used for writing in the same manner as the conventional SRAM cell.

Therefore, during a writing operation in the SRAM cell supporting transposed reading, a cell value of a row selected by the wordline WWL is overwritten as in the conventional SRAM and transposed writing which simultaneously changes a cell value of the same column is not supported.

During a reading operation in the SRAM cell supporting transposed reading, the read transistor M7 added to a conventional SRAM cell structure is used. In a state in which the voltage of the storage node Q in which a value is stored is applied to the gate of the transistor M7, if a row is selected through the wordline H_RDWL for reading shared by cells in the same row, a value stored in a cell is read through the bit line H_RDBL for reading shared by cells in the same column.

In the SRAM cell supporting transposed reading, during transposed reading operation for reading a value stored in corresponding cells by selecting one column together with a conventional reading scheme for reading a value stored in corresponding cells by selecting one row through the wordline H_RDWL for reading, the wordline H_RDWL and the bit line H_RDBL are operated in a transposed manner.

That is, during transposed reading, roles of the two metal lines are transposed such that the vertical metal line is used as the wordline and the vertical metal line is used as the bit line.

Therefore, when transposed reading is performed, the bit line H_RDBL is used as the wordline V-RDWL to select one column and the wordline H_RDWL is used as the bit line V-RDBL to read values stored in cells of the selected column.

Therefore, during transposed reading, the roles of the two metal lines are transposed such that the vertical metal line is used as the wordline and the horizontal metal line is used as the bit line. In this case, the source and the drain of the transistor M7 may be connected in a transposed manner.

Meanwhile, in the conventional SRAM cell, since only cells in the same row or the same column can be read, if multiple bits constituting one word are stored in the same row or the same column in the same bank, it is possible to simultaneously read data only during either reading or transposed reading and it is impossible to simultaneously read the word during both reading and transposed reading.

Accordingly, when a T-SRAM according to the present invention is used, a word consisting of multiple bits is written and then one SRAM bank is allocated to each bit constituting the word in order to identically read bits of the word during both reading and transposed reading.

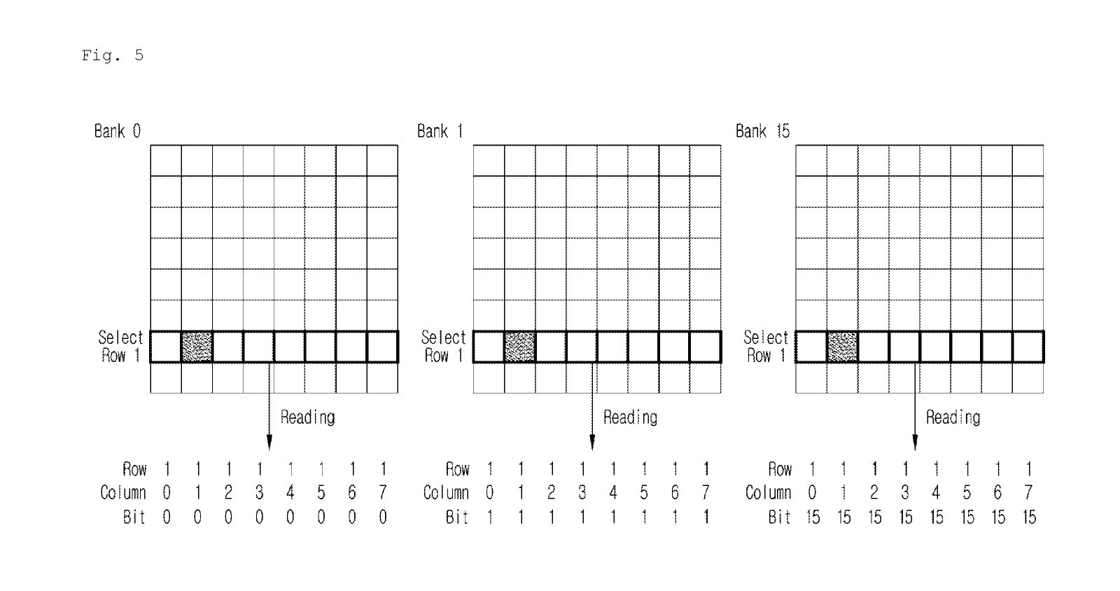

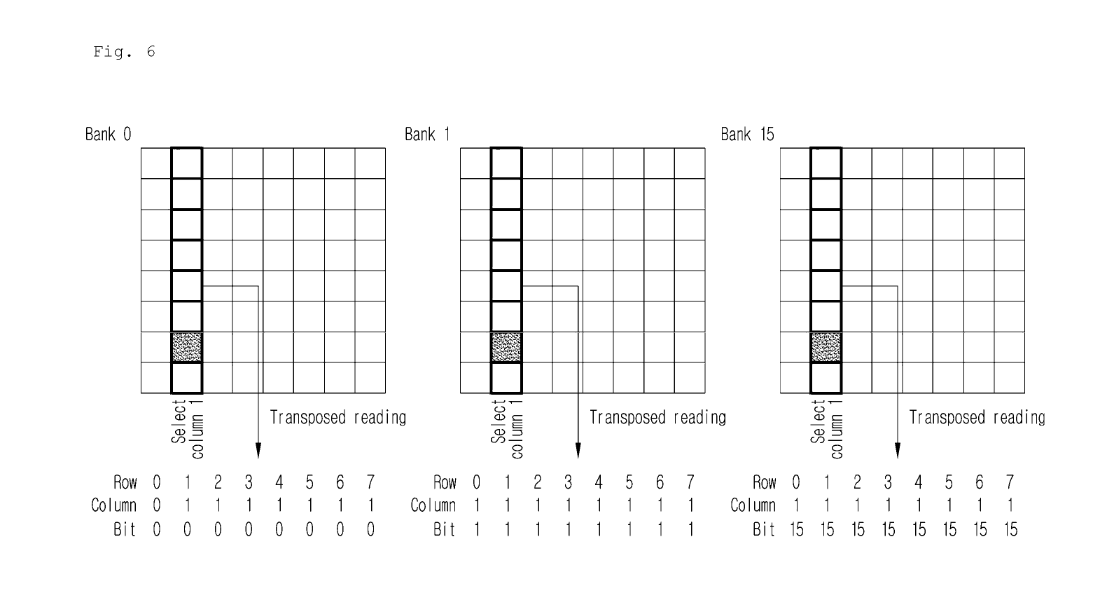

FIG. 5 illustrates an example of providing 16 banks for storing a 16-bit word when reading is performed by selecting a row 1. FIG. 6 illustrates an example of providing 16 banks for storing a 16-bit word when transposed reading is performed by selecting a column 1.

Accordingly, when reading for the row 1 is performed and transposed reading for the column 1 is performed by allocating one SRAM bank to each bit constituting a word, the same value can be read from a word of the row 1 and the column 1 located at an overlapping part because the same cells are selected from the 16 banks.

According to the SRAM structure supporting transposed reading of the present invention as described above, the SRAM cell is constructed by 7 transistors supporting transposed reading in addition to normal reading and writing, thereby retrieving a plurality of data through one-time reading even during column-wise parallel processing as well as row-wise parallel processing. As a result, delay caused by multiple-time reading and increase in power consumption, occurring in a conventional SRAM, can be solved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A static random access memory (SRAM) structure supporting transposed reading, comprising:
a T-SRAM comprising:
a 6-transistor SRAM cell including four transistors constituting two storage nodes in the form of an inverter latch and two access transistors connected between the storage nodes and two bit lines of the cell under control of a wordline signal; and
a read transistor,
wherein a gate terminal of the read transistor is connected to one of the two storage nodes and the other two terminals of the read transistor are respectively connected to a first metal line shared by cells in the same row and a second metal line shared by cells in the same column,
wherein, during row-wise reading and column-wise transposed reading through the read transistor, a plurality of data is read by a one-time reading operation.

2. (canceled)

3. The SRAM structure according to claim 2, wherein,
during the row-wise reading through the read transistor, the first metal line is a horizontal metal line being used as a wordline and the second metal line is a vertical metal line being used as a bit line and,
during the column-wise transposed reading through the read transistor, the vertical metal line is used as the wordline and the horizontal metal line is used as the bit line.

4. The SRAM structure according to claim 1, wherein the T-SRAM cell stores data including a plurality of bits by allocating one bank to each bit so that data allocated to the same position is read during the row-wise reading and the column-wise transposed reading.

5. (canceled)
